(19) United States
(12) Patent Application Publication
(10) Pub. No.: US 2011/0023611 A1
(43) Pub. Date: Feb. 3, 2011

(54) SELF-HEALING COMPOSITE MATERIAL

(75) Inventors: Frank Jones, Derbyshire (GB); Simon A. Hayes, Sheffield (GB)

Correspondence Address: POLSINELLI SHUGHART PC, 700 W. 47TH STREET, SUITE 1000, KANSAS CITY, MO, 64112-1802, US

(73) Assignee: THE UNIVERSITY OF SHEFFIELD, Sheffield (GB)

(21) Appl. No.: 12/874,303

(22) Filed: Sep. 2, 2010

Related U.S. Application Data
(63) Continuation of application No. 10/585,883, filed on Jul. 23, 2007, now abandoned.

(30) Foreign Application Priority Data
Jan. 9, 2004 (GB) 0400403.2
Jul. 29, 2004 (GB) 0416927.2

(51) Int. Cl. G01N 29/04; B32B 5/00; B32B 5/02; B32B 27/04; B32B 5/12; C08L 71/00; C08L 61/22; C08L 67/00; C08L 75/04; C08L 63/00; C08L 33/02; C08L 27/12; B05D 3/02; G01R 27/08; B32B 43/00

(52) U.S. Cl. 73/629; 428/297.4; 428/221; 428/298.1; 428/298.7; 428/299.1; 428/299.4; 428/113; 442/172; 442/178; 442/179; 442/180; 524/611; 524/597; 524/599; 524/589; 523/468; 524/556; 524/545; 427/385.5; 427/386; 73/627; 324/722; 156/94

(57) ABSTRACT

A self-healing composite material comprising a fibre-reinforced polymeric matrix, wherein the polymeric matrix comprises a thermosetting polymer and a thermoplastic polymer.

The present invention relates to self-healing composite materials, and more particularly to a self-healing composite material comprising a fibre-reinforced polymeric matrix.

Since the development of structural glass and carbon fibre composites, there has been a progressive increase in their uses in structural applications. These range from civil infrastructure, such as bridges and tunnels, to high performance vehicles such as racing cars and military aircraft. In all these applications the specific mechanical properties of the composite are utilised to give improvements in structural efficiency over corresponding metallic structures. However, there remain concerns about the effects of impact damage on the structural integrity of such composite materials.

Damage resulting from impact can cause a loss of 50-60% of the undamaged static strength. The ability to repair a composite material mainly depends on two factors, early stage detection of the damage and accessibility. Detection of low velocity impact damage is very difficult and it is also difficult to access the resulting deep cracks in the composite material to facilitate repair. The damage can be divided into two types, macro-damage and micro-damage. Macro-damage mainly results from extensive delaminating, ply-buckling and large-scale fracture and can be visually detected and repaired with reasonable ease. However, micro-damage, which is barely visible, consisting of small delaminations, ply-cracks and fibre-fracture, occurs mainly inside the composite material, and is consequently much more difficult to detect and repair.

In most composite materials, the fibres bear the majority of the applied force. For low velocity impacts, the ability of the fibres to store energy elastically is of fundamental importance in ensuring excellent impact resistance. However the matrix also has a role in impact resistance. Non-destructive testing (NDT) methods have identified a number of failure mechanisms in polymer matrix composites, allowing the detection of barely visible damage. Such methods are at present essential for its identification and repair.

There are many different kinds of damage that can be present in an impact-damaged composite material. These include shear-cracks, delamination, longitudinal matrix-splitting, fibre/matrix debonding and fibre-fracture. The relative energy absorbing capabilities of these fracture modes depend on the basic properties of the fibres, the matrix and the interphase region between the fibres and the matrix, as well as on the type of loading. Fibre-breakage occurs in the fibres, matrix-cracking takes place in the matrix region, and debonding and delamination occur in the interphase region and are very much dependent on the strength of the interphase.

There are a variety of NDT inspection techniques available for the in-situ detection of impact damage in composite materials. These include visual inspection, ultrasonic inspection, vibrational inspection, radiographic inspection, thermographic inspection, acoustic emission inspection and laser shearography.

All of the above NDT damage detection techniques have some disadvantages and so have not proved 100% efficient, especially in the case of low velocity damage. These inspection techniques are time-consuming and are always carried out on a scheduled basis. If any damage occurs just after an inspection it will remain undetected until the next scheduled inspection, which may allow damage growth to occur and lead to catastrophic failure. Also, the inspection techniques are dependent on the skill of the operator to carry out the appropriate procedure. In the case of low velocity impact damage, barely visible impact damage frequently remains unidentified even after many scheduled inspections.

Smart sensors have been proposed to overcome the limitations of conventional NDT methods. These include optical strain gauges using Fabry-Perot interferometers, Bragg grating sensors and intensity based sensors operating on the principle that crack propagation will fracture an optical fibre causing a loss of light.

Electrical systems have also been proposed, for monitoring changes in the resistance or conductance of a composite. A resistance-based detection method is disclosed in an article by Hou & Hayes in Smart Mater. & Struct. 11, (2002) 966-969. This technique is based on the principle that, when damaged, a carbon fibre panel will show a greater resistance as compared to its pre-damaged state, allowing the damage to be detected. If the location of the change in resistance can be determined, damage location also becomes possible. The method involves the embedding of thin metallic wires at the edge of the composite material and monitoring the resistance between aligned pairs of wires. When damage occurs an increase in resistance is observed between pairs that are close to the damage. The entire disclosure of this article is incorporated herein by reference for all purposes.

Repair of defects in materials caused by in-service damage is generally necessitated by impact rather than by fatigue. Once the defect has been located by a suitable NDT method, a decision must be made as to whether the part should be replaced or repaired. Repair techniques vary greatly depending on the type of structure, materials and applications, and the type of damage. The options include bonded-scarf joint flush repair, double-scarf joint flush repair, blind-side bonded scarf repair, bonded external patch repair and honeycomb sandwich repair.

Thermoplastic matrix based composites are also susceptible to impact damage. These are usually repaired by fusion bonding, adhesive bonding or by mechanical fastening. Mechanical joints can also be made using conventional bolts, screws, or rivets, although care must be taken to ensure the fastener does not itself induce further damage.

There are a number of disadvantages of conventional repair techniques for polymer-based composite materials. For example, almost all of the above repair techniques require some manual intervention, and are therefore dependent on the skill of the repairer. As a result of these problems, composite materials have found limited use in areas such as consumer transport applications.

Self-repair techniques have also been proposed to increase the safety of composite materials, maintain structural integrity and reduce procurement and maintenance costs. Such techniques are “passive”, that is to say, they are initiated by the damage itself. In these techniques healing starts without any kind of monitoring. It is not possible to determine whether damage in the composite material has been healed properly or not, however, without using NDT techniques.

U.S. Pat. No. 5,989,334 and U.S. Pat. No. 6,527,849 describe a self-repairing, fibre reinforced matrix material having disposed within the matrix hollow fibres having a selectively releasable modifying agent contained therein.

S. M. Bleay et al. Composites: Part A 32, 1767-1776 (2001) also describes a technique for the repair of delaminations in polymer composites using hollow fibres which act as structural reinforcement as well as containers for the repair resin. The hollow fibres are filled with resin, which is released into the damaged area when the fibres are fractured. A two-part epoxy resin is used, the two components being diluted with solvent and infiltrated into different plies of a glass fibre composite.

However, the use of substantial amounts of hollow fibre can reduce the mechanical properties of the whole composite significantly, by reducing the fibre volume fraction.

An analysis of the mechanism of impact damage in composite materials shows that the damage initially starts in the matrix region and not in the fibres. Therefore, unless the hollow fibres are substantially weaker than conventional reinforcing fibres they will not fracture under light impact loads. However, without fibre fracture, healing is impossible using the hollow fibre technique. The fabrication of such self-repairable composite materials is difficult and low viscosity epoxy resin is required to fill the hollow fibres. Entire removal of solvents from the composite material is impossible, and there is a chance of gas bubble formation in the composite material during curing. Further, an on-board damage detection system is still needed to detect and monitor the extent of damage and the efficacy of healing. Finally, the improvements observed are still minimal (˜10% strength recovery) compared to the strength of the undamaged composite.

In Nature 409, 794-817 (2001) and U.S. Pat. No. 6,518,330 S. R. White et al. propose self-healing by incorporating a microencapsulated healing agent and catalytic chemicals that trigger the healing process within an epoxy matrix. An approaching crack ruptures embedded microcapsules, releasing healing-agent into the crack-plane through capillary action. Polymerisation of the healing-agent is triggered by contact with the embedded catalyst, bonding the crack-faces together. The damage induced triggering mechanism provides site-specific autonomic control of repair. Also by using a living polymerisation catalyst (with very low termination rate) multiple healing events can occur.

However, filling of the matrix resin with microcapsules containing the healing agent and fabrication of the composite is very complicated. Improper impregnation of the matrix will lead to areas of variable volume fraction, causing a reduction in strength, and there is a chance of voids forming in the final composite.

M. Motuku et al. Smart-Materials and Structures 8, 623-638 (1999) have proposed self-healing by using both hollow fibres and micro-capsules as healing material containers.

The present invention provides an improved self-healing composite material wherein, in certain preferred embodiments, detection and repair of damaged areas can be initiated and monitored. The composite material comprises a self-healing polymeric matrix comprising a thermosetting polymer and a thermoplastic polymer. In certain preferred embodiments the composite material comprises a self-healing polymeric matrix together with a reinforcing material.

According to a first aspect of the invention there is provided a self-healing composite material comprising a fibre-reinforced polymeric matrix, wherein the polymeric matrix comprises a thermosetting polymer and a thermoplastic polymer that together form a solid solution.

In a second aspect, the invention provides a method for producing a self-healing composite material, which comprises impregnating a layer, mat or tow of reinforcing fibres with a polymeric matrix comprising a thermosetting polymer and a thermoplastic polymer that together form a solid solution.

In a preferred embodiment of the composite material of the invention, the reinforcing fibres comprise carbon fibres.

In a third aspect, the invention also provides a self-healing composite material comprising a fibre-reinforced polymeric matrix, wherein the polymeric matrix comprises a thermosetting polymer and a thermoplastic polymer, and wherein detection means are provided to detect the presence and preferably the location of at least one damaged area of the composite material.

In a fourth aspect, the invention also provides a self-healing composite material comprising a fibre-reinforced polymeric matrix, wherein the fibre reinforcement comprises carbon fibres and the polymeric matrix comprises a thermosetting polymer and a thermoplastic polymer, and wherein detection means are provided to detect a change in resistance of the composite material, said change in resistance indicating the presence of at least one damaged area of the composite material.

In a fifth aspect, the invention provides a method of detecting the presence of a damaged area in a self-healing composite material comprising a fibre-reinforced polymeric matrix, wherein the fibre reinforcement comprises carbon fibres and the polymeric matrix comprises a thermosetting polymer and a thermoplastic polymer, which comprises detecting a change in resistance of the composite material indicating the presence of at least one damaged area.

In a sixth aspect, the invention provides a method of repairing a damaged area in a self-healing composite material comprising a fibre-reinforced polymeric matrix, wherein the polymeric matrix comprises a thermosetting polymer and a thermoplastic polymer, which comprises heating the damaged area to the fusion temperature of the thermoplastic polymer for a time sufficient to promote damage repair.

In a seventh aspect, the invention provides a self-healing polymeric matrix for a composite material, which comprises a blend of a thermosetting polymer and a thermoplastic polymer that together form a solid solution.

By “self-healing composite material” in this specification is meant a composite material that is capable of substantial recovery of its load transferring ability after damage. Such recovery can be passive, for example, where the composite material comprises liquid resin that can flow and fill cracks, with subsequent hardening in place. Alternatively the recovery can be active, that is to say the composite material requires an external stimulus, for example, heating of the damaged area. In preferred embodiments of the invention, the self-healing composite material is capable of recovering 50% or more, 60% or more, 70% or more, or 80% or more, of its load transferring ability.

The self-healing composite material of the invention can be shaped to any desired form, for example, sheets, tubes, rods, and moulded articles. Preferably the composite material comprises a laminate of two, or more, reinforcing fibre layers impregnated with a polymeric matrix.

The reinforcing fibres can comprise, for example, carbon fibres, glass fibres, ceramic fibres, metal fibres, or mixtures thereof. Preferably the reinforcing fibres are laid in the form of a mat, an aligned layer or a tow. Especially where the reinforcing fibres comprise carbon fibres, these are preferably laid in one or more layers such that the fibres in each layer are axially aligned. Where more than one layer of axially aligned fibres are present, the layers are preferably arranged so that the axes of fibres in different layers lie at an angle to each other. The angle can, for example, be from 15° to 90°. The reinforcing fibres are preferably continuous, although healing is also achievable in short fibre composites containing any fibre type.

The composite material can also comprise a reinforcing material other than fibres, for example, organic and/or inorganic fillers. In certain circumstances these can replace the fibrous reinforcement wholly or partly.

The thermosetting polymer can be any suitable polymer into which reinforcement, and particularly reinforcing fibres, can be incorporated. Examples of suitable thermosetting polymers include phenolic resins; phenol-formaldehyde resins; amine-formaldehyde resins, for example, melamine resins; urea-formaldehyde resins; polyester resins; urethane resins; epoxy resins; epoxy-polyester resins; acrylic resins; acrylic-urethane resins; fluorovinyl resins; cyanate ester resins; polyimide resins and any other related high temperature thermosetting resin.

The thermoplastic polymer preferably has a fusion temperature or flow temperature significantly above ambient temperature, but not so high as to cause thermal breakdown of the thermosetting polymer. Preferably, the thermoplastic polymer has a fusion or flow temperature that is similar to the glass transition temperature of the thermosetting polymer, preferably in the range of Tg±100° C., more preferably Tg±50° C., most preferably Tg±10° C.

In the first, second and seventh aspects of the present invention, the thermosetting polymer and the thermoplastic polymer together form a solid solution. In this specification, a “solid solution” is intended to denote a homogeneous mixture of two or more components which substantially retains the structure of one of the components.

The polymeric matrix preferably comprises at least 5% by weight of the thermoplastic polymer, more preferably from 5 to 50% by weight, most preferably from 10 to 30% by weight, based upon the total weight of the polymer matrix. In a preferred embodiment, the thermoplastic polymer is uniformly dispersed throughout the polymeric matrix, being wholly miscible with the thermosetting polymer. In this specification, such a dispersion of a thermoplastic polymer in a thermosetting polymer is referred to as a “polymer solution”. The invention is not, however, limited to polymer solutions, and in certain embodiments of the third, fourth, fifth and sixth aspects of the invention any matrix in which the thermoplastic polymer can bridge defects, for example, cracking, and thereby promote healing is also included. Examples of other suitable polymeric matrices include those comprising interleaved layers of thermoplastic polymer and thermosetting polymer, and composite materials with modified fibre polymeric coatings.

Suitable thermoplastic polymers for use with epoxy resins include, for example, polybisphenol-A-co-epichlorohydrin. Preferably the thermoplastic polymeric is miscible with the thermosetting polymer, but does not normally chemically react with it at ambient temperatures. In this way, a suitable thermoplastic polymer can be selected for any thermosetting polymer system.

In the first, second and seventh aspects of the invention, it is preferred that the thermoplastic polymer forms a homogeneous solution with the thermosetting matrix, both before and after cure. This is a relatively rare occurrence for polymers, which generally display poor miscibility in each other, particularly as their molecular weight increases. Several methods for determining suitable combinations are possible, and one preferred approach is outlined below. The thermoplastic polymer healing agent chosen for use with the thermosetting polymer matrix can be selected using thermodynamic principles. One such approach is the “solubility parameter” which is defined as the square root of the cohesive energy density. Thus polymers with similar solubility parameters (δ) are compatible (Brydson, J.A. Plastics Materials, Butterworths Publishers, 5^{th} Edition, 1989). When the solubility parameter of the thermoplastic polymer is within 2 MPa^{1/2} of that of the thermosetting polymer matrix they will remain compatible.

δ_{thermoplastic}=δₜₕₑᵣₘₒₛₑₜ±2 MPa^{1/2} 1

or δ_{thermoplastic}=δₜₕₑᵣₘₒₛₑₜ±1 Cal^{1/2} cm^{-3/2} 2

Equally the value of δ for either component can be calculated from the fundamental structure of the polymer using molar attraction constants (G)

δ=ρΣG/M 3

where ρ=density, M=molecular weight of the segment.

Representative values of G are given by Small P. A. (J. Appl. Chem. 1953, 3, 71)

Furthermore for polymer solutions used as matrices for composites, the thermodynamics of the mixture can be adjusted to ensure that self healing occurs. This can be formalised through

δₛₒₗᵤₜᵢₒₙ=x₁δ₁+x₂δ₂ 4

where χ₁ and χ₂ are the mole fractions of components 1 and 2 of solubility parameter δ₁ and δ₂.

Using the above method, a chemically compatible thermoplastic polymer can be selected for any thermosetting polymer system. It is then necessary to ensure that the healing rate is acceptable, by careful selection of the molecular weight of the thermoplastic polymer and the healing temperature that is employed. As the healing process is thought to be a diffusional one, lower molecular weight will give more rapid diffusion and therefore quicker healing. However, the mechanical properties of the thermoplastic polymer improve with greater molecular weight. A balance therefore exists between rapid healing and good healed mechanical properties, which can in part be mitigated by using the healing temperature as a second variable. In order to select the optimum molecular weight of the thermoplastic polymer, the Tg of the thermosetting polymer must be taken into account as well, as it is necessary for the Tg of the thermoplastic polymer to be similar to that of the thermosetting polymer if healing is to be successful. For any compatible thermoplastic polymer the best compromise can be therefore be attained by consideration of the compatibility of the polymers (as laid out above), the Tg of the thermosetting polymer, the molecular weight of the thermoplastic polymer and the healing temperature that is to be employed.

The self-healing composite material can be produced, for example, by forming a solution of the thermosetting polymer and the thermoplastic polymer, impregnating a layer of reinforcing fibres with the polymer solution thus produced, and curing the thermosetting polymer.

In one preferred embodiment of the invention the self-healing composite material is provided with damage detection means for detecting and locating damaged areas of the composite material. Such detection means can, for example, detect a change in a physical parameter of the composite material caused either directly or indirectly by the damage. Suitable physical parameters can include, for example, light reflection, acoustic wave propagation and electrical resistance.

In one embodiment, the self-healing composite material is provided with means for generating acoustic waves in the material. Such acoustic waves are preferably ultrasonic waves, more preferably acousto-ultrasonic guided waves, and most preferably Lamb waves. Typically such generating means can include, for example, one or more transducers or actuators, especially piezoelectric transducers and actuators. Means for detecting acoustic waves reflected from a damaged area may include, for example, fibre Bragg grating sensors, as described by Betz D. C. et al, 2^{nd} European Workshop on Structural Health Monitoring, Munich, Jul. 7-9, 2004, or a multi-point laser scanning vibrometer, as described by Leong W. H. et al, 2^{nd} European Workshop on Structural Health Monitoring, Munich, Jul. 7-9, 2004. Preferably, however, the composite material is provided with one or more piezoelectric transducers, preferably surface mounted, that can act as both wave propagators and receivers. Such transducers are described by Valdes S. H. D. and Soutis C. in Journal of the Acoustical Society of America 2002, vol 111, Issue 5, pages 2026-2033 and Plastics and Rubber Composites 2000, vol 29, Issue 9, pages 475-481. The location of a damaged area, for example, a delamination, can be determined using an array of spaced apart surface mounted transducers and analysing the reflected Lamb waves.

Where the self-healing composite material is provided with resistance-based damage detection means, the detection means preferably comprises one or more electrodes in electrical contact with the carbon fibres of the fibre reinforcement. Preferably a plurality of spaced apart electrodes are provided, being disposed along one or more edge regions of the composite material. In a preferred embodiment, the carbon fibres are aligned axially, and the electrodes are connected to opposed ends of the carbon fibres, forming aligned pairs. In a particularly preferred embodiment, the composite material comprises a laminate of two or more fibre reinforcing layers, wherein the carbon fibres of a first layer are aligned at an angle to the carbon fibres of a second layer, and each layer is separately provided with electrodes connected to its carbon fibres. This requires the inclusion of an interleaf as outlined in Hou & Hayes in Smart Materials and Structures 11, (2002). A particularly preferred damage detection system employing a plurality of spaced apart electrodes mounted on an electrically insulating substrate and electrically connected to the electrically conducting fibres is described and claimed in concurrently filed UK Patent Application No. (Agents reference no. P109009GB). In this preferred damage detection system the electrically insulating substrate is preferably flexible. It can, for example, comprise a polymeric sheet or film, especially a sheet or film of polymeric material of the type used for flexible printed circuit boards. The electrically insulating substrate can be used as an interleaf and can isolate the electrically conductive fibres from the composite if required. The electrodes may be applied to the electrically insulating substrate by any suitable method. They can, for example, be laid down as thin strips of metal or electrodeposited onto the surface of the substrate. Alternatively the electrodes can be etched from a metal film, preferably a copper film, bonded to the electrically insulating substrate.

The entire disclosure of UK Patent Application No. (Agents reference no. P109009 GB) is incorporated herein by reference for all purposes.

The electrodes can be connected to suitable resistance measuring and monitoring means. The resistance measuring and monitoring means is capable of detecting changes in resistance of a composite material, which changes may result from damage to the fibres, the polymer matrix, or the interphase region. Where a plurality of layers of carbon fibres is provided, and the carbon fibres in separate layers are aligned at an angle to one another, the resistance measuring and monitoring means can also provide an output indicating the position of the area of damage by triangulation. A suitable resistance-based detection method is disclosed by Hou & Hayes in Smart Materials & Structures 11, (2002). However, it should be noted that alternative damage detection systems such as optical fibre sensors can also be employed to identify the damage and allow the manual initiation of healing.

When the presence, and preferably also the location, of a damaged area in the composite material has been detected, the area can be healed, for example, by heating the damaged area to a temperature at or above the fusion temperature of the thermoplastic polymer. Without wishing to be constrained by any particular theory, it is believed that heating causes the thermoplastic polymer to fuse and flow, sealing cracks and restoring integrity to the composite material.

In a preferred embodiment of this aspect of the invention, the composite material comprises carbon fibres and the damaged area is heated by passing a current through the carbon fibres, at least in the damaged area. The carbon fibres in the damaged area have a higher resistance than carbon fibres in surrounding areas and therefore will be preferentially heated, causing localised heating of the polymeric matrix in the damaged area. Preferably the damaged area is heated to a temperature of from Tg_{thermoplastic} to Tg_{thermoplastic}+75° C., more preferably in the range of Tg_{thermoplastic}+30° C. to Tg_{thermoplastic}+60° C.

Preferably the damaged area is heated for the shortest possible time that facilitates good healing. The actual heating time can be optimised empirically, and will depend on the molecular weight of the thermoplastic polymer, the Tg of the thermosetting polymer and the temperature employed for healing. In a preferred embodiment, this would require a heating regime that is completed in less than 1 hour and more preferably in less than 5 minutes. Those skilled in the art will be able to determine by simple experiment or observation the balance to be struck between the length of time necessary to obtain healing, and the temperature at which either structural rigidity is too greatly compromised, or chemical decomposition of one of the phases occurs.

In the Examples below, a healing time of 90 minutes was employed to allow a standard for both sample types that gave the reference “resin only” sample the best chance of healing. It therefore does not represent an optimised condition, with healing of a good standard having been obtained, for example, after heating for 30 minutes, using a preferred solution of polymers in accordance with the invention.

Various embodiments of the invention will now be described and illustrated in the following non-limiting Examples.

### EXAMPLE 1

This example describes a comparison between the fracture toughness of test specimens before and after damage and healing. The specimens were prepared from a thermoset epoxy resin system alone and from the same epoxy resin system having 25 weight % of a thermoplastic polymer dissolved therein.

In the epoxy resin-only specimens, 15 g Vantico Araldite LY 1556 aromatic epoxy, 10 g Araldite GY298 aliphatic epoxy, 15.96 g nadic methylene anhydride (NMA) hardener and 5.95 g Henkel Chemicals Capcure 3-800 accelerator were mixed thoroughly to ensure a uniform resin blend. The mixture was de-gassed in a vacuum oven and cast in a mould to form a block. The mixture was cured for 4 hours at 80° C. and post-cured for 3 hours at 120° C. The cured block was machined into test specimens in accordance with BS ISO 13586:2000.

For the thermoplastic polymer containing specimens, polybisphenol-A-co-epichlorohydrin was first mixed at 25 weight % with a mixture of 15 g LY 1556 aromatic epoxy and 10 g GY298 aliphatic epoxy and vigorously stirred overnight. The mixture was heated to 120° C. for 45 minutes to aid dissolution of the thermoplastic, and cooled to room temperature. Subsequently 15.96 g NMA (nadic methyl anhydride) hardener and 5.95 g Capcure 3-800 accelerator was added to the mixture. The same curing schedule was used as for the epoxy resin only specimens.

The specimens were tested in accordance with the procedure set out in BS ISO 13586:2000 and displacement versus load graphs plotted. The sharp notch of the compact-tension specimen allows crack propagation through the specimen.

The Tg of the polybisphenol-A-co-epichlorohydrin was determined by dynamic mechanical thermometric analysis (DMTA) to be approximately 80° C. and healing was therefore carried out at temperatures from 100° C. to 140° C.

To assist in healing the fractured specimens, a G-clamp was used to lightly clamp the two halves together. Healing was carried out at temperatures from 100° C. to 140° C. in 10° C. intervals. All of the samples were kept at the healing temperature in an oven for 90 minutes and allowed to cool overnight.

From the results of the compact-tension testing, values of the critical stress concentration factor ‘K_{Q}’ and critical strain energy release rate ‘G_{Q}’ were calculated using the equations set out in BS ISO 13586:2000

Displacement versus load graphs were plotted to compare the results of all of the tests with different conditions. Also from the graph, critical stress intensity factor (K_{Q}) and critical strain energy release rate (G_{Q}) were calculated using the equation given in the standard.

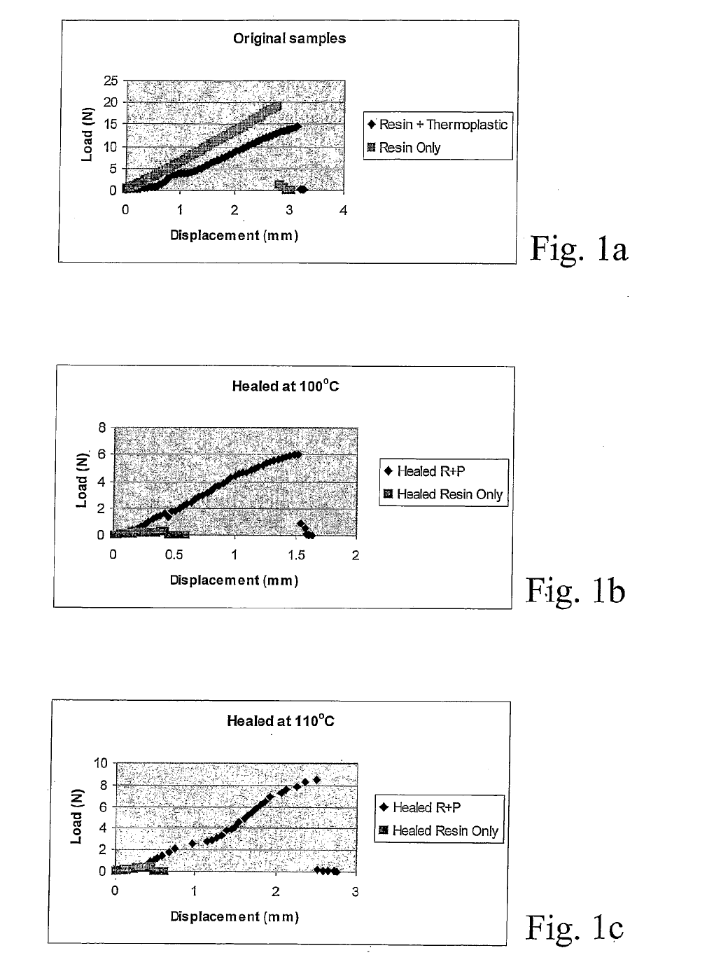

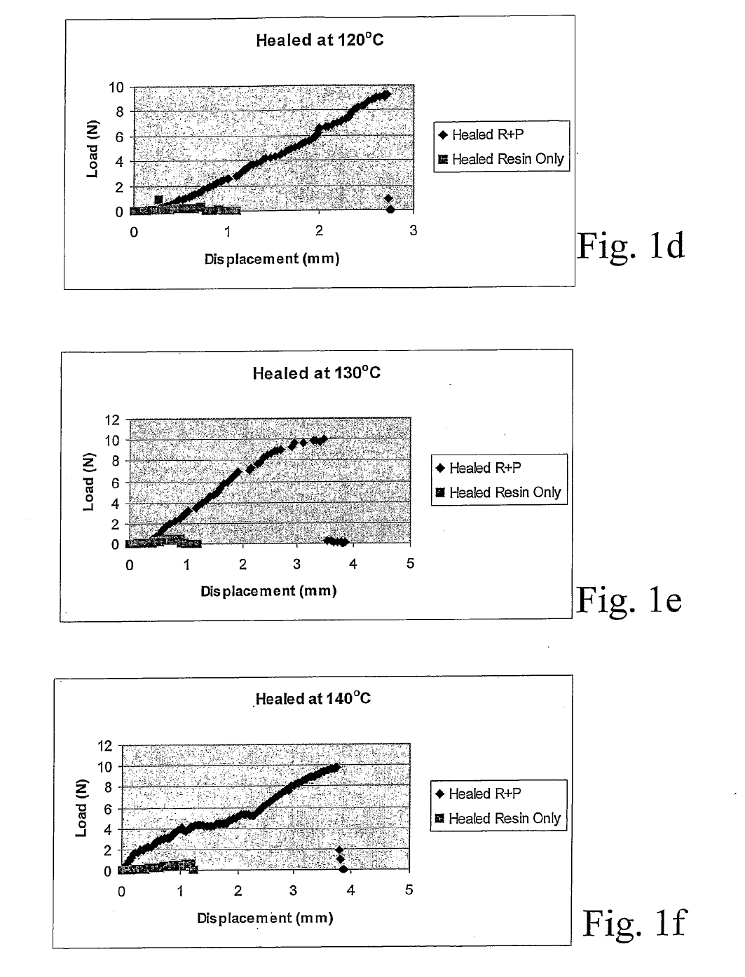

FIG. 1(a) shows results for compact-tension tests of the resin-only original specimen and the resin-thermoplastic solution original specimen. It can be seen that the nature of the curves are similar, but that they have different peak load and displacement values. The subsequent graphs (FIGS. 1(b) to 1(f)) show significant healing in the resin and thermoplastic solution specimens, but no significant recovery in the resin only specimens.

TABLE 1
Showing Peak values of load to break and
corresponding displacement of original and healed
compact-tension specimens.

| | Peak Load (N) | | | |
|---|---|---|---|---|
| | | Resin- | Displacement (mm) | |
| | | thermo- | | Resin- |
| Compact-tension | | plastic | | thermoplastic |
| Specimens | Resin-only | solution | Resin-only | solution |
| Original | 20 ± 0.50 | 15 ± 0.5 | 2.8 ± 0.25 | 3.20 ± 0.25 |
| Healed at 100° C. | 0.26 ± 0.02 | 6 ± 0.5 | 0.5 ± 0.05 | 1.50 ± 0.30 |
| Healed at 110° C. | 0.35 ± 0.05 | 8 ± 0.5 | 0.6 ± 0.05 | 2.50 ± 0.25 |
| Healed at 120° C. | 0.50 ± 0.05 | 09 ± 0.5 | 1.0 ± 0.05 | 2.75 ± 0.25 |
| Healed at 130° C. | 0.60 ± 0.10 | 9.5 ± 0.5 | 1.0 ± 0.10 | 3.25 ± 0.25 |
| Healed at 140° C. | 0.70 ± 0.75 | 10 ± 0.5 | 1.1 ± 0.10 | 3.75 ± 0.25 |

Table 1 shows values of peak load and corresponding displacements for all sample types, including the standard deviations calculated from three repeats. It can be seen that for the original samples, the resin-only sample has a higher peak load than the resin-thermoplastic solution specimens. Also the corresponding displacements of these two specimens are different and the resin-thermoplastic solution specimens show higher displacement than the resin-only specimen.

Similarly, in all cases the healed specimens show some recovery of peak load and displacement, although in the case of healed resin-thermoplastic solution specimens recovery is significantly higher than that for the healed resin-only specimens at all of the healing temperatures. It can be seen that the peak values of load, and the corresponding displacements, of healed resin-thermoplastic solution specimens were steadily increasing with higher healing temperatures. The peak load values of healed resin and thermoplastic solution specimens at 100° C. is approximately 6 N, whereas at 140° C. it is approximately 10 N. Similarly the value of displacement at 100° C. is 1.5 mm, and that for healed specimens at 140° C. is 3.75 mm. So from Table 1 the trends of peak loads and displacements in healed resin-thermoplastic solution specimens at different healing temperatures from 100° C. to 140° C. are showing a steady increase in their values.

In the case of the healed resin-only specimens at all of the healing temperatures, there is no significant change in the values of peak load and displacements and the value is very low.

Table 2 shows results for the critical stress concentration factor (K_{Q}) and critical strain energy release rate (G_{Q}) of the two specimen types before and after healing. It can be seen that values of K_{Q} and G_{Q} are higher in the case of the original resin-only specimens than the original resin-thermoplastic solution specimens. Also from Table 2, it can be seen that values of K_{Q} and G_{Q} are higher in the case of the healed resin-thermoplastic solution specimens than for the healed resin-only specimens at all of the healing temperatures. Further, there is a steady increase in the values of K_{Q} and G_{Q} in the case of healed resin-thermoplastic solution specimens at higher healing temperatures. In the case of the healed resin-only specimens this change is minimal even at increased healing temperatures.

TABLE 2
Critical stress concentration factor ‘K_{Q}’
and strain energy release factor ‘G_{Q}’ of original and
healed compact-tension specimens.

| | Critical stress concentration | | Strain energy release rate | |
|---|---|---|---|---|
| | Factor ‘K_{Q}’ (MPa mm^{0.5}) | | ‘G_{Q}’ (kJ/m²) | |
| Compact-tension | | Resin-thermoplastic | | Resin-thermoplastic |
| Specimens | Resin-only | solution | Resin-only | solution |
| Original | 3.17 ± 0.070 | 2.52 ± 0.145 | 260 ± 15 | 220 ± 17 |
| Healed at 100° C. | 0.04 ± 0.000 | 1.06 ± 0.082 | 1 ± 0.00 | 50 ± 6 |
| Healed at 110° C. | 0.07 ± 0.003 | 1.34 ± 0.041 | 2 ± 0.00 | 110 ± 2 |
| Healed at 120° C. | 0.05 ± 0.002 | 1.50 ± 0.062 | 2 ± 0.00 | 120 ± 4 |
| Healed at 130° C. | 0.09 ± 0.005 | 1.57 ± 0.047 | 3 ± 0.00 | 150 ± 15 |
| Healed at 140° C. | 0.11 ± 0.001 | 1.62 ± 0.085 | 4 ± 0.00 | 170 ± 9 |

From Table 1 and Table 2, the healed resin-thermoplastic solution specimens show a steady increase in peak load, displacement, and K_{Q} and G_{Q} values, whereas the healed resin-only specimen show very little evidence of healing. This increase in healing in the resin-thermoplastic solution specimens is thought to be because of diffusion of the thermoplastic molecules across the fracture as the healing temperature increases, allowing greater intermingling between the two fractures surfaces. However, in case of the resin-only specimens, the degree of diffusion is minimal because all of the resin in the resin-only specimen is cured and cannot intermingle to any significant extent.

Tables 3 and 4 show the healing efficiencies of healed resin-only specimens and healed resin-thermoplastic solution specimens, compared to the original resin-only and resin-thermoplastic specimens respectively. Healing efficiencies have been calculated using the simple equation below (equation 5).

$$Healing Efficiency = \frac{{}_{}^{‵}{{K}_{Q}}{}_{}^{′} or {}_{}^{‵}{{G}_{Q}}{}_{}^{′} for healed specimen}{{{}_{}^{‵}{K}{}_{Q}^{}}^{′} or {}_{}^{‵}{{G}_{Q}}{}_{}^{′} for the original specimen} \qquad 5$$

TABLE 3
Healing efficiencies of the healed resin-only
and healed resin-thermoplastic solution specimens in
comparison to the resin-only original specimens in terms
of their ‘K_{Q}’ and ‘G_{Q}’ values.

| | Healing efficiency | | | |
|---|---|---|---|---|
| | in terms of ‘K_{Q}’ | | Healing efficiency in terms | |
| | compared to the | | of ‘G_{Q}’ compared to | |
| | original resin-only | | the original resin- | |
| | samples (%). | | only samples (%). | |
| | | Resin- | | Resin- |
| Compact-tension | Resin- | thermoplastic | | thermoplastic |
| Specimens | only | solution | Resin-only | solution |
| Original | 100 | 79 | 100 | 85 |
| Healed at 100° C. | 1.3 | 33.4 | 0.2 | 19.5 |
| Healed at 110° C. | 2.3 | 42.4 | 0.6 | 40.0 |
| Healed at 120° C. | 1.8 | 47.2 | 0.6 | 43.9 |
| Healed at 130° C. | 2.8 | 49.7 | 1.0 | 56.3 |
| Healed at 140° C. | 3.4 | 51.0 | 1.4 | 63.6 |

TABLE 4
Healing efficiencies of the healed resin-only
and healed resin-thermoplastic solution specimens in
comparison to the resin-thermoplastic solution original
specimens in terms of ‘K_{Q}’ and ‘G_{Q}’ values.

| | Healing efficiency | | | |
|---|---|---|---|---|
| | in terms of ‘K_{Q}’ | | Healing efficiency | |
| | compared to the | | in terms of ‘G_{Q}’ | |
| | original resin- | | compared to the | |
| | thermoplastic solution | | original resin-thermoplastic | |
| | samples (%). | | solution samples (%). | |
| | | Resin- | | Resin- |
| Compact-tension | Resin- | thermoplastic | Resin- | thermoplastic |
| Specimens | only | solution | only | solution |
| Original | 126 | 100 | 118 | 100 |
| Healed at 100° C. | 1.6 | 39.3 | 0.2 | 22.0 |
| Healed at 110° C. | 2.7 | 49.9 | 0.7 | 45.2 |
| Healed at 120° C. | 1.9 | 55.5 | 0.7 | 49.5 |
| Healed at 130° C. | 3.3 | 58.5 | 1.1 | 63.6 |
| Healed at 140° C. | 4.0 | 60.0 | 1.6 | 71.7 |

It can be seen that the healing efficiency of the healed resin-thermoplastic specimens is far greater than that of the healed resin-only specimens. The values of healing efficiency for the healed resin-only specimens in terms of both ‘K’ and ‘G’ values are very low, there is not any significant increase in their efficiencies with increased healing temperature, and they remain at a constant lower value.

For the resin-thermoplastic solution specimens, it can clearly be observed that the healing efficiency has been increased as healing temperature is increased. As healing temperature varies from 100° C. to 140° C., there is a significant increase in the interaction between both of the fracture surfaces, which results in increased efficiency in terms of both K_{Q} and G_{Q}. At a healing temperature of 140° C., there is a 51% recovery with respect to original resin-only specimen and 60% recovery with respect to resin-thermoplastic solution original specimen in terms of K_{Q}. Also at the same healing temperature, there is 63% recovery with respect to original resin-only specimen and 71% recovery with respect to resin-thermoplastic solution original specimen in terms of G_{Q}.

The healing temperature was not increased beyond 140° C., as above this temperature substantial loss in dimensional stability of the specimen was observed.

### EXAMPLE 2

This example describes the localised heating of a damaged area using a resistance-based sensor.

Specimens were fabricated from Hexcel FIBREDUX: 913C-HTA(121e)-5-346 carbon-fibre pre-preg with 913 matrix resin system, using the lay up sequence [0₂/90₂/0₃/90₃]ₛ. Metal wires were embedded at 5 mm intervals parallel to the direction of the fibres just below the specimen surface.

The location of a damaged area in a specimen, induced by a falling dart impact tester, was determined using the resistance-based sensor and method of Hou and Hayes Smart Mater. Struc. 11 (2002) 966-969.

Once the location of the damage had been determined by the appropriate resistance measurements, the following procedure was carried out to establish a localised heating effect:

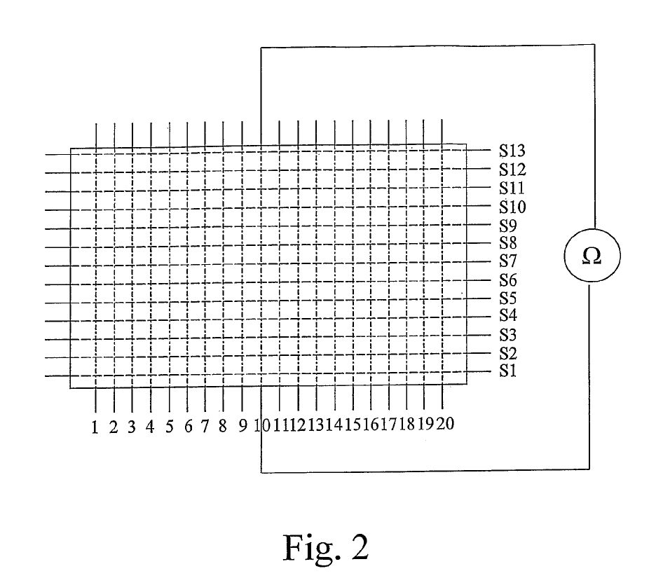

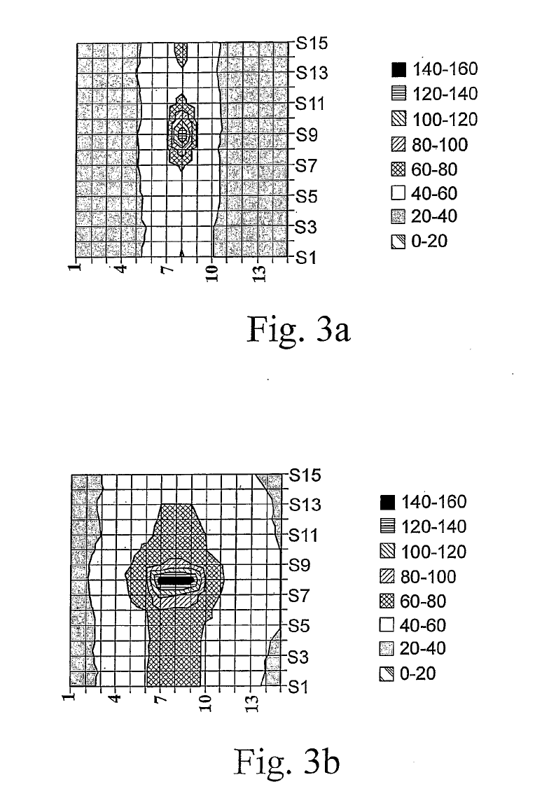

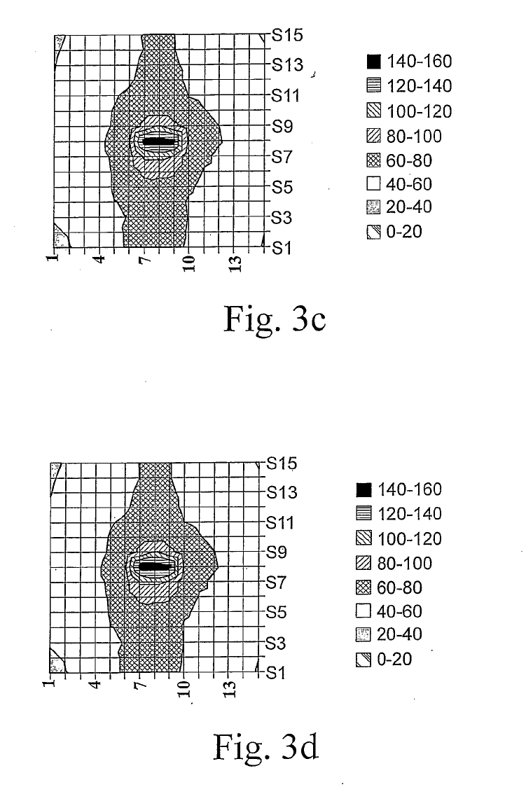

1] The specimen was connected as shown in FIG. 2 with the opposite ends being used to form a simple electrical circuit.
2] Initially the current was passed through the panel using a central single pair of wires that were in line with the damaged zone (Pair 10 in FIG. 2). A current of approximately 1.5 A and a voltage of 6 V were applied. This was kept constant throughout all of the tests.
3] Corresponding changes in the temperature of the whole specimen were measured using a thermocouple applied to the surface of the sample, by superimposing a grid of 5 mm×5 mm on the composite specimen. The temperature at each vertex was measured.
4] Subsequently three wires from each side, again those in line with the damage (9, 10, 11 in FIG. 3) were selected and the temperature changes in each vertex were measured. The same procedure was repeated for increasing number of wires by selecting five (8, 9, 10, 11, 12) and seven (7, 8, 9, 10, 11, 12, 13) on each side of the specimen, the temperature data being recorded in each case.

FIG. 3 shows the local temperature across the panel in both X and Y directions for each number of connected wires.

FIG. 3a shows the temperature throughout the specimen when current (1.5 A) is passed through 1 metallic sensor wire. The different shades in the graphs show different temperature zones. From the legend on the right hand side of the graph it can be seen that at the centre there is a significantly higher temperature as compared to the other parts of the specimen. Also from the centre of the specimen, the temperature reduces going towards the edges of the sample. However, this reduction in temperature is lower in the ‘Y’ direction than in the ‘X’ direction. The size of the zone that is heated to a temperature above 140° C. and above 80° C. for each different number of sensor wires is shown in Table 5.

TABLE 5
The different sizes of heating zones above 140° C.
and above 80° C. for different numbers of sensor wires in a
panel measuring 10 cm * 7 cm.

| | Size above 140° C. | | Size above 80° C. | |
|---|---|---|---|---|
| Number of | (cm) | | (cm) | |
| connected | ‘Y’ | ‘X’ | ‘Y’ | ‘X’ |
| wires | Direction | Direction | Direction | Direction |
| [1] | 0.5 | 0.25 | 1.5 | 0.75 |
| [3] | 0.5 | 1 | 1.75 | 2 |
| [5] | 0.5 | 1 | 2.25 | 2 |
| [7] | 0.5 | 1 | 2.25 | 2 |

From the above table it can be seen that the areas of the panel above each temperature increased as number of connected wires is increased. The area with a surface temperature above 140° C. size for 1 pair of sensing wires is 0.5×0.25 cm². This increased to 0.5×1 cm² when 7 pairs of contact wires were connected. Similarly the surface area above 80° C. for 1 pair of connected wires is 1.5×0.75 cm², increasing to 2.25×2 cm² when 7 pairs of wires are connected.

Penetrant enhanced X-ray analysis was employed to allow measurement of the damage area present in the sample. The specimens used were identical to those used in the study of localised heating.

The experimental procedure is as follows:

1] First the penetrant mixture was prepared using four different chemicals which are as follows, with their relative composition, 5 g Zinc Iodide, 10 ml Distilled water, 10 ml Methylated spirit, 0.5 ml Kodak photo-flo. This mixture was then kept in the oven at 50° C.
2] The specimen was drilled, using a 1 mm diameter drill at the centre of the damaged zone. A region around the hole was sealed to ensure no leakage of the penetrant when it was applied. The penetrant was then injected into the specimen.
3] After leaving overnight to allow the penetrant to fill the cracks, the specimens were analysed using X-radiography.
4] The specimens were placed into the instrument ensuring they were flat and perpendicular to the beam.
5] Using a voltage of 40 kV the film was exposed for 12 seconds. Then using developer the X-ray image was developed.

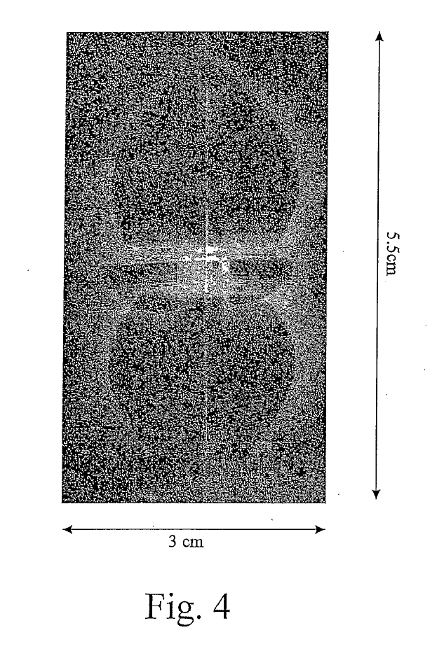

FIG. 4 shows the impact damage area in the damaged sample, obtained using penetrant enhanced X-ray analysis. It can be observed that the extent of the impact damage is greater in the vertical direction than in the horizontal. The X-ray film only covers an area of 3 cm horizontal and 5.5 cm vertical and therefore, it can be determined that the central damage area is 4.25×2.25 cm².

The results from the temperature measurement and the observed damage-zone size can be compared. Table 5 shows that there is an increase in the localised heated area in the vertical direction moving from 1 wire to 7 pairs of contact wires. By comparison between FIG. 4 and Table 5, the locally heated area seen when connected to 1 pair of wires, for which the temperature is above 80° C., only covers 35% of the damaged zone as measured using the X-ray analysis. Also when 3 pairs of sensor wires are connected, the region that is above 80° C. represents 90% in X direction and 40% in Y direction of the damaged zone and for 5 and 7 sensor wires, heated zone is approximately correct in the X direction but only 50% in the Y direction where delamination dominates the damage. Connecting 5 or 7 wires gives a heated zone that encompasses the central damage zone. So from the results shown in Table 5 and FIG. 4, it can be stated that the size of the impact damaged area, as determined using x-ray analysis of the resistance-based sensor (Hou and Hayes, Smart Materials and Structures, 11, (2002)) can be used to determine the number of wires that need to be connected to a power supply in order to get an exact locally heated area with respect to the impact damage area. Also as the locally heated area seen in both of the surface graphs (FIGS. 3c and 3d) are similar to each other, it can be noted that connection of a greater number of sensor wires is not necessary.

### EXAMPLE 3

This example describes a self-healing polymeric matrix in accordance with the invention based on diglycidyl ether of bisphenol A (DGEBA) and an aliphatic polyamine.

Epoxy resin rods were produced by mixing Huntsman LY564 resin (DGEBA) and Huntsman HY2954 hardener in the ratio 100:30 and dissolving polybisphenol-A-co-epichlorohydrin in the resin at either 5% or 10% of the total sample weight. Comparison rods without the polybisphenol-A-co-epichlorohydrin were also formed. The rods were cured for 2 hours at 60 C and 8 hours at 120° C. These rods were then notched and snapped, to create a fracture surface, and were clamped back together before being heated as before to 130° C. for 90 minutes. After this treatment, qualitatively it was observed that the rods that contained healing agent (polybisphenol-A-co-epichlorohydrin) had regained more strength than those which did not contain any healing agent.

### EXAMPLE 4

This example describes composite self-healing panels in accordance with the invention and a method for their production.

The composite panels were produced using the resin composition of Example 1, with 60% of Huntsman LY1556 (or Shell Epikote 828), and 40% of Huntsman GY298, into which had been dissolved 10% of the sample weight of polybisphenol-A-co-epichlorohydrin. This was cured with NMA at 63 per hundred of resin and Henkel Capcure 3-800 at 21 per hundred of resin. This mixture was heated and forced in to a mat of glass fibres that had been dry-wound on to a frame, so that the fibres ran in two perpendicular directions in the approximate proportions of 50-60% by weight of the fibres. The result was a panel which had a volume fraction of fibres in the range 50-60% and consisted of a central 90 degree ply that was twice as thick as the outer 0 degree plies (one on each face of the panel. Specimens were cut from the panel and impacted using a Davenport uninstrumented falling-dart impact tester at an incident impact energy of 2.7 J. The damage inflicted on the specimens was observed under transmitted light and photographs taken. The specimens were then placed in an oven at 130° C. for 60 minutes, before removal and reexamination.

The images were then analysed using image analysis software to determine the damage-zone size, and the % recovery in area upon healing in each case was determined as (1−(area after healing)/(area before healing))×100.

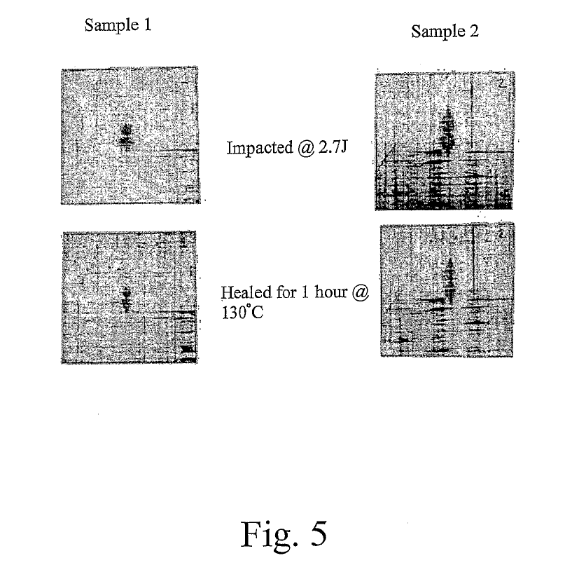

FIG. 5 shows photographs illustrating the damage present in the specimens before and after a healing step is applied. Upon impact, a peanut-shaped delamination is formed in the structure, and can be seen roughly in the centre of each panel as a darkened zone. It is also possible to see matrix cracks emanating from the damage zone as darkened lines. As can be seen, after a healing step has been applied the damage is significantly reduced over the as-impacted materials, and the matrix cracks have largely disappeared. Image analysis has shown that the reduction in area equates to 38% for sample 1 and 27% for sample 2, indicating that a significant proportion of the fracture area has been healed at the edges of the delaminated zone in both samples.

The reader's attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of any foregoing embodiments. The invention extends to any novel one, or any novel combination, of the features disclosed in this specification (including any accompanying claims, abstract and drawings), or to any novel one or any novel combination, of the steps of any method or process so disclosed.

FIG. 1: Graphs showing Displacement (mm) vs. Load (N) for (a) original resin only and resin and thermoplastic blend specimens, (b) both healed at 100° C., (c) both healed at 110° C., (d) both healed at 120° C., (e) both healed at 130° C., (f) both healed at 140° C.

FIG. 2: Circuit diagram for localised heating of the panel.

FIG. 3: Surface graphs showing the temperature throughout the sample a] For 1 connected sensor wire. b] For 3 connected sensor wires. c] For 5 connected sensor wires. d] For 7 connected sensor wires.

FIG. 4: Impact damage area in the sample by X-ray radiographic NDT test.

FIG. 5: Photographs showing the damage present in healable composites before and after a healing steps have been applied. It can be seen that the delamination area is reduced and visible matrix cracks have been eliminated.

1. A self-healing composite material comprising a fibre-reinforced polymeric matrix, wherein the polymeric matrix comprises a thermosetting polymer and a thermoplastic polymer that together form a solid solution.

2. A composite material according to claim 1, wherein the reinforcing fibres comprise carbon fibres.

3. A composite material according to claim 1 or 2, which comprises a laminate of two or more reinforcing fibre layers impregnated with a polymeric matrix.

4. A composite material according to any one of the preceding claims, wherein the reinforcing fibres comprise carbon fibres, glass fibres, ceramic fibres, metal fibres and metal coated reinforcing fibres, or mixtures thereof.

5. A composite material according to claim 4, wherein the reinforcing fibres are laid in the form of a mat, aligned layer or tows.

6. A composite material according to any one of the preceding claims, wherein the reinforcing fibres are laid in one or more layers and the fibres in each layer are axially aligned.

7. A composite material according to claim 6, wherein the layers are arranged so that the axes of fibres in different layers lie at an angle to each other.

8. A composite material according to claim 7, wherein the axes of the fibres lie at an angle of from 15° to 90° to each other.

9. A composite material according to any one of the preceding claims, wherein the reinforcing fibres are present as continuous fibres or short fibres within the matrix.

10. A composite material according to any one of the preceding claims, wherein the thermosetting polymer comprises a phenolic resin, a phenol-formaldehyde resin, an amine-formaldehyde resin, a urea-formaldehyde resin, a polyester resin, a urethane resin, an epoxy resin, an epoxy-polyester resin, an acrylic resin, an acrylic-urethane resin, a fluorovinyl resin; a cyanate ester resin; a polyimide resin or any other related high temperature thermosetting resin.

11. A composite material according to claim 10, wherein the thermosetting polymer comprises an epoxy resin cured with a curing agent comprising an anhydride or an amine.

12. A composite material according to any one of the preceding claims, wherein the thermosetting polymer has a glass transition temperature Tg and the thermoplastic polymer has a fusion or flow temperature in the range Tg±100° C.

13. A composite material according to claim 12, wherein the thermoplastic polymer has a fusion or flow temperature in the range Tg±50° C.

14. A composite material according to claim 12 or 13, wherein the thermoplastic polymer has a fusion or flow temperature in the range of Tg±10° C.

15. A composite material according to any one of the preceding claims, which comprises from 5 to 50% by weight of the thermoplastic polymer, based upon the total weight of the polymeric matrix.

16. A composite material according to any one of the preceding claims, wherein the thermoplastic polymer is wholly miscible with the thermosetting resin.

17. A composite material according to any one of the preceding claims, wherein the thermosetting polymer is an epoxy resin and wherein the thermoplastic polymer is polybisphenol-A-co-epichlorohydrin.

18. A composite material according to any one of the preceding claims, wherein the thermoplastic polymer does not chemically react with the thermosetting polymer at ambient temperatures.

19. A composite material according to any one of the preceding claims, wherein the thermoplastic polymer and the thermosetting polymer are selected such that the solubility parameter of the thermoplastic polymer is within 2 MPa^{1/2} of that of the thermosetting polymer.

20. A composite material according to any one of the preceding claims substantially as described in the Examples.

21. A composite material substantially as hereinbefore defined.

22. A method for producing a self-healing composite material, which comprise impregnating a layer of reinforcing fibres with a polymeric matrix comprising a thermosetting polymer and a thermoplastic polymer that together form a solid solution.

23. A method according to claim 22, which comprise forming a solution of a prepreg of the thermosetting polymer and the thermoplastic polymer, impregnating a layer of reinforcing fibres with the solution thus produced, and curing the thermosetting polymer.

24. A method according to claim 22 or 23, wherein the thermosetting polymer comprises a phenolic resin, a phenol-formaldehyde resin, an amine-formaldehyde resin, a urea-formaldehyde resin, a polyester resin, a urethane resin, an epoxy resin, an epoxy-polyester resin, an acrylic resin, an acrylic-urethane resin, a fluorovinyl resins; a cyanate ester resin; a polyimide resin or other high temperature thermosetting resin.

25. A method according to any one of claims 22 to 24, wherein the thermosetting polymer is an epoxy resin and the thermoplastic polymer is polybisphenol-A-co-epichlorohydrin.

26. A method according to any one of claims 22 to 25, wherein the thermoplastic polymer does not chemically react with the thermosetting polymer at ambient temperatures.

27. A method according to any one of claims 22 to 26, wherein the thermoplastic polymer is wholly miscible with the thermosetting polymer.

28. A method of producing a self-healing composite material substantially as described in the Examples.

29. A method of producing a self-healing composite material substantially as hereinbefore described.

30. A composite material according to any of one of claims 1 to 21 that has been produced by a method according to any one of claims 22 to 29.

31. A self-healing composite material comprising a fibre-reinforced polymeric matrix, wherein the polymeric matrix comprises a thermosetting polymer and a thermoplastic polymer, and wherein detection means are provided to detect the presence of at least one damaged area of the composite material.

32. A composite material according to claim 31, wherein detection means are provided to detect the presence and location of at least one damaged area of the composite material.

33. A composite material according to claim 31 or 32, wherein the detection means detects a change in a physical parameter of the composite material caused either directly or indirectly by the damage.

34. A composite material according to any one of claims 31 to 33, wherein the detection means detects a change in acoustic wave propagation or electrical resistance.

35. A composite material according to claim 34, wherein the self-healing composite material is provided with means for generating acoustic waves in the material and means for detecting acoustic waves reflected from a damaged area.

36. A composite material according to claim 35, wherein the acoustic waves are ultrasonic waves.

37. A composite material according to claim 36, wherein the ultrasonic waves are acousto-ultrasonic guided waves.

38. A composite material according to claim 37, wherein the ultrasonic waves are Lamb waves.

39. A composite material according to any one of claims 35 to 38, wherein the means for generating acoustic waves comprises one or more piezoelectric transducers or actuators.

40. A composite material according to any one of claims 35 to 39, wherein the means for detecting acoustic waves reflected from a damaged area comprises a fibre Bragg grating sensor, or a multi-point laser scanning vibrometer.

41. A composite material according to any one of claims 35 to 39, wherein the means for detecting acoustic waves reflected from a damaged area comprises one or more piezoelectric transducers that can act as both wave propagators and receivers.

42. A composite material according to any one of claims 32 to 34, wherein detection means are provided to detect a change in resistance of the composite material, said change in resistance indicating the presence of at least one damaged area of the composite material.

43. A composite material according to claim 42, wherein the reinforcing fibres comprise carbon fibres and the detection means comprises one or more electrodes in electrical contact with the carbon fibres.

44. A composite material according to claim 43, wherein a plurality of spaced apart electrodes is provided, disposed along one or more edge regions of the composite material.

45. A composite material according to claim 43 or 44, wherein the carbon fibres are aligned axially and the electrodes are connected to opposed ends of the carbon fibres.

46. A composite material according to any one of claims 43 to 45, wherein the composite material comprises a laminate of two or more fibre reinforcing layers, each containing carbon fibres, wherein the carbon fibres of a first layer are aligned at an angle to the carbon fibres of a second layer, and wherein each layer is separately provided with electrodes connected to its carbon fibres.

47. A composite material according to claim 46, wherein the electrodes are connected to a resistance measuring and monitoring means having an output providing an indication of the position of an area of damage.

48. A composite material provided with damage detection means according to any one of claims 31 to 47 substantially as hereinbefore described.

49. A method of detecting the presence of a damaged area in a self-healing composite material comprising a reinforced polymeric matrix, wherein the reinforcement comprises carbon fibres and the polymeric matrix comprises a thermosetting polymer and a thermoplastic polymer, which comprises detecting a change in resistance of the composite material indicating the presence of at least one damaged area.

50. A method according to claim 49, wherein there is used a composite material provided with damage detection means according to any one of claims 42 to 49.

51. A method of detecting the presence of a damaged area in a self-healing composite material substantially as described in the Examples.

52. A method of detecting the presence of a damaged area in a self-healing composite material substantially as hereinbefore described.

53. A method of repairing a damaged area in a self-healing composite material comprising a fibre-reinforced polymeric matrix, wherein the polymeric matrix comprises a thermosetting polymer and a thermoplastic polymer, which comprises heating the damaged area to the fusion temperature of the thermoplastic polymer.

54. A method according to claim 53, wherein there is used a composite material according to any one of claims 1 to 21 and 31 to 48.

55. A method according to claim 53 or 54, wherein the damaged area is heated to a temperature of from the Tg of the thermoplastic polymer to Tg+75° C.

56. A method according to claim 55, wherein the damaged area is heated to a temperature of from Tg+30° C. to Tg+60° C.

57. A method according to any one of claims 53 to 56, wherein the damaged area is heated for a time optimised to give maximum healing.

58. A method according to claim 57, wherein the damaged area is heated for a time of from 5 to 60 minutes.

59. A method according to any one of claims 53 to 58, wherein the composite material comprises carbon fibres and the damaged area is heated by passing a current through the carbon fibres, at least in the damaged area.

60. A method according to any one of claims 53 to 59, wherein the carbon fibres are used both for detection of the damaged area and for heating of the damaged area by resistance heating.

61. A method of repairing a composite material substantially as herein before described.

62. A self-healing polymeric matrix for a composite material which comprises a blend of a thermosetting polymer and a thermoplastic polymer that together form a solid solution.
